(19) United States
(12) Patent Application Publication
(10) Pub. No.: US 2024/0224468 A1
(43) Pub. Date: Jul. 4, 2024

(54) IMMERSION COOLING SYSTEM AND DELIVERY DEVICE THEREOF

(71) Applicant: Wiwynn Corporation, New Taipei City (TW)

(72) Inventor: Hsien-Chieh Hsieh, New Taipei City (TW)

(73) Assignee: Wiwynn Corporation, New Taipei City (TW)

(21) Appl. No.: 18/136,884

(22) Filed: Apr. 20, 2023

(30) Foreign Application Priority Data
Dec. 29, 2022 (TW) 111150600

(51) Int. Cl. H05K 7/20

(52) U.S. Cl. CPC H05K 7/20327; H05K 7/20236

(57) ABSTRACT

A delivery device includes a first base, two first check valves, a carrier, a first deformable container and a driving mechanism. The first base has a first inlet and a first outlet. The two first check valves are disposed at the first inlet and the first outlet. The first deformable container is connected to the first base and the carrier. The first deformable container communicates with the first inlet and the first outlet. The driving mechanism is connected to the carrier. The driving mechanism drives the carrier to reciprocate, such that the carrier drives the first deformable container to expand or contract.

### BACKGROUND OF THE INVENTION

### 1. Field of the Invention

The invention relates to an immersion cooling system and a delivery device thereof and, more particularly, to a delivery device capable of preventing a delivered fluid from being contaminated and an immersion cooling system equipped with the delivery device.

### 2. Description of the Prior Art

An immersion cooling system uses a cooling liquid to dissipate heat from electronic components by a phase change manner. The cooling liquid evaporates into gas after absorbing the heat generated by the electronic component. The immersion cooling system is usually equipped with a delivery device for delivering and recycling the gas. The conventional delivery device disposes a plunger in a chamber and the plunger needs a mechanical seal, so as to deliver a fluid by the reciprocation of the plunger in the chamber. However, when the plunger reciprocates in the chamber, the mechanical seal has a leakage concern, such that it is not suitable for processing or delivering a volatile chemical fluid and the delivered fluid are at risk of contamination.

### SUMMARY OF THE INVENTION

According to an embodiment of the invention, a delivery device comprises a first base, two first check valves, a carrier, a first deformable container and a driving mechanism. The first base has a first inlet and a first outlet. The two first check valves are disposed at the first inlet and the first outlet. The first deformable container is connected to the first base and the carrier. The first deformable container communicates with the first inlet and the first outlet. The driving mechanism is connected to the carrier. The driving mechanism drives the carrier to reciprocate, such that the carrier drives the first deformable container to expand or contract.

According to another embodiment of the invention, an immersion cooling system with a delivery device comprises a cooling tank, a cooling device and the delivery device. The cooling device is connected to the cooling tank. The delivery device comprises a first base, two first check valves, a carrier, a first deformable container and a driving mechanism. The first base has a first inlet and a first outlet, wherein the first inlet is connected to the cooling tank and the first outlet is connected to the cooling device. The two first check valves are disposed at the first inlet and the first outlet. The first deformable container is connected to the first base and the carrier. The first deformable container communicates with the first inlet and the first outlet. The driving mechanism is connected to the carrier. The driving mechanism drives the carrier to reciprocate, such that the carrier drives the first deformable container to expand or contract.

As mentioned in the above, the invention connects the deformable container and the driving mechanism to the carrier. When the driving mechanism drives the carrier to reciprocate, the carrier drives the deformable container to expand or contract, so as to deliver a fluid through the inlet and the outlet of the base. Since the driving mechanism is connected to the carrier, the driving mechanism is not in contact with the fluid in the deformable container. Accordingly, the delivery device of the invention can prevent the delivered fluid from being contaminated by the driving mechanism. Furthermore, the deformable container and the driving mechanism can be disassembled and assembled separately, such that the maintenance is simple.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a delivery device according to an embodiment of the invention.

FIG. 2 is an exploded view illustrating the delivery device shown in FIG. 1.

FIG. 3 is a perspective view illustrating a first check valve shown in FIG. 1.

FIG. 4 is a sectional view illustrating an immersion cooling system equipped with the delivery device shown in FIG. 1.

FIG. 5 is a sectional view illustrating a carrier of the delivery device shown in FIG. 4 moving upward.

FIG. 6 is a sectional view illustrating the carrier of the delivery device shown in FIG. 4 moving downward.

FIG. 7 is a perspective view illustrating the delivery device according to another embodiment of the invention.

FIG. 8 is a perspective view illustrating the delivery device according to another embodiment of the invention.

### DETAILED DESCRIPTION

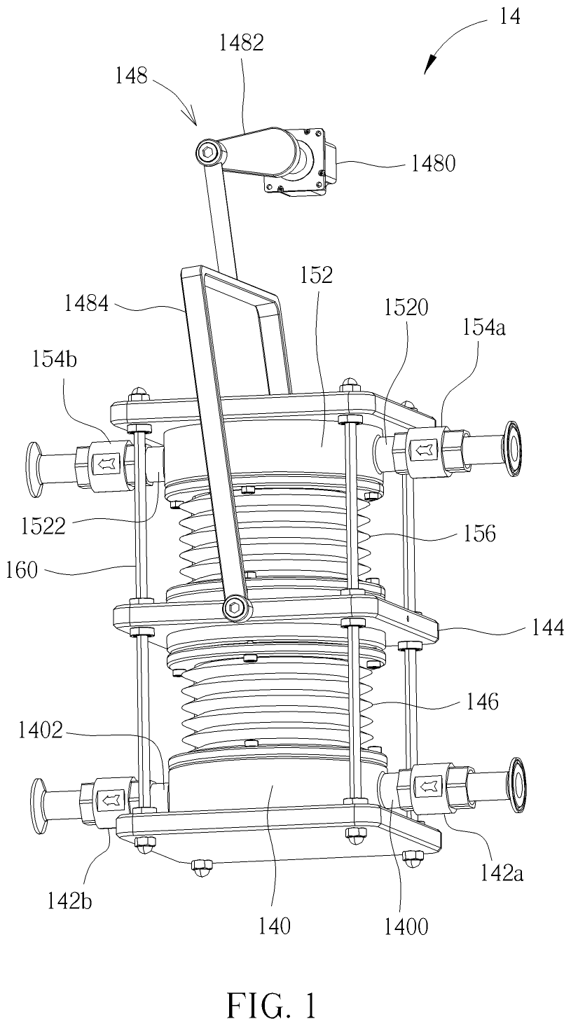

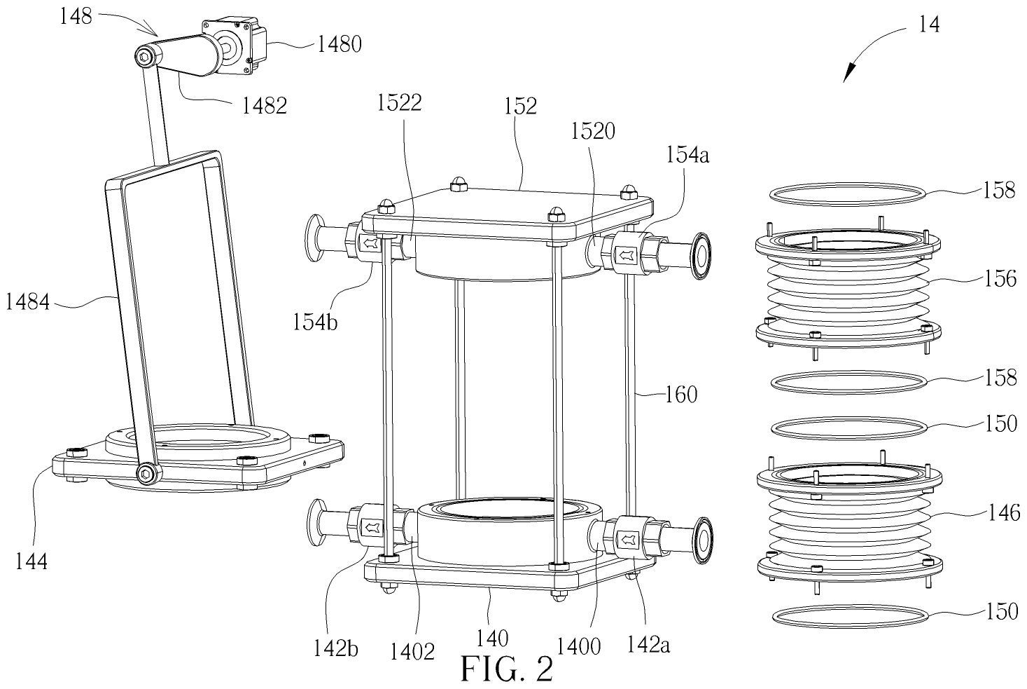

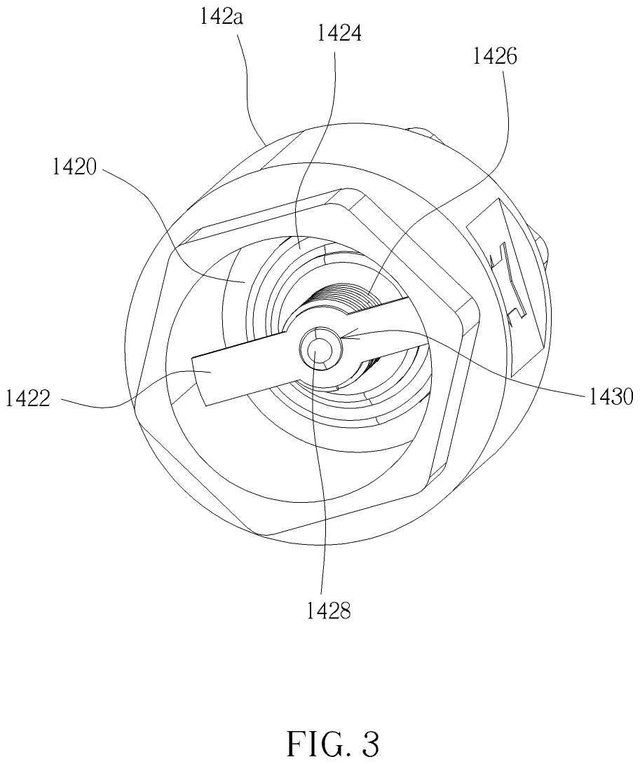

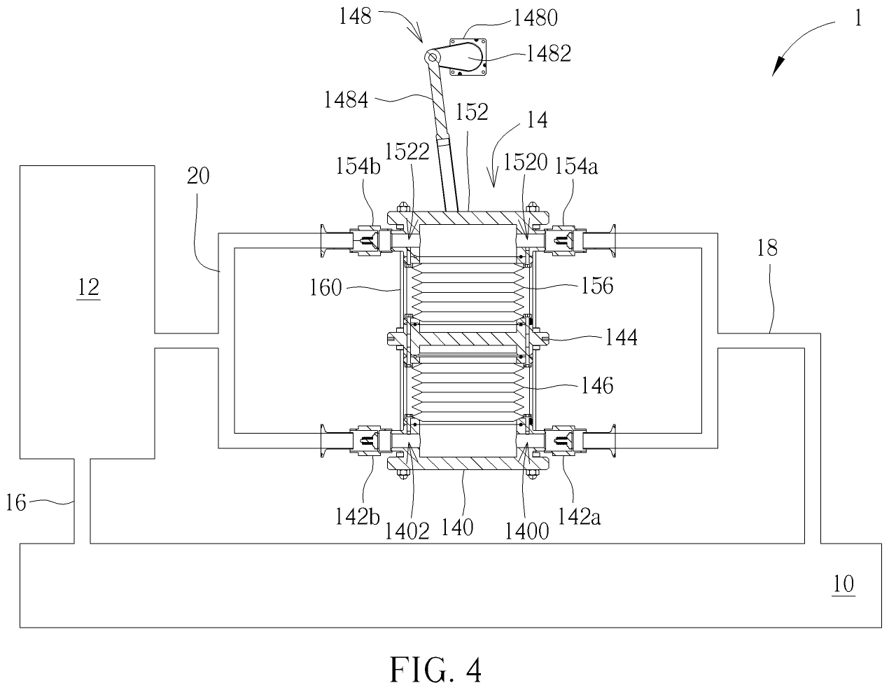

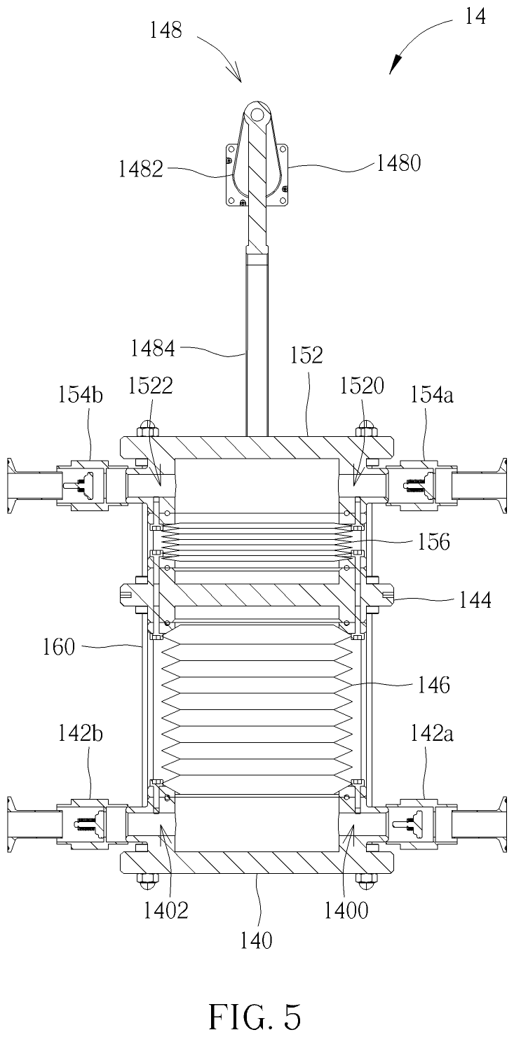

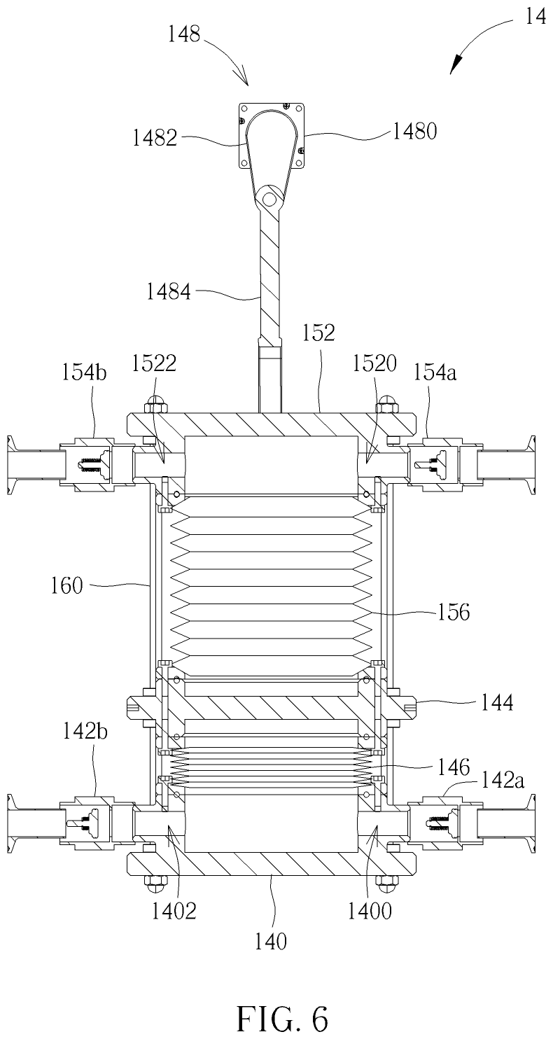

Referring to FIGS. 1 to 6, FIG. 1 is a perspective view illustrating a delivery device 14 according to an embodiment of the invention, FIG. 2 is an exploded view illustrating the delivery device 14 shown in FIG. 1, FIG. 3 is a perspective view illustrating a first check valve 142a shown in FIG. 1, FIG. 4 is a sectional view illustrating an immersion cooling system 1 equipped with the delivery device 14 shown in FIG. 1, FIG. 5 is a sectional view illustrating a carrier 144 of the delivery device 14 shown in FIG. 4 moving upward, and FIG. 6 is a sectional view illustrating the carrier 144 of the delivery device 14 shown in FIG. 4 moving downward.

As shown in FIGS. 1 to 4, the delivery device 14 comprises a first base 140, two first check valves 142a, 142b, a carrier 144, a first deformable container 146, a driving mechanism 148, two first sealing members 150, a second base 152, two second check valves 154a, 154b, a second deformable container 156, two second sealing members 158 and a plurality of support members 160.

The first base 140 has a first inlet 1400 and a first outlet 1402. The two first check valves 142a, 142b are disposed at the first inlet 1400 and the first outlet 1402. The first deformable container 146 is connected to the first base 140 and the carrier 144, and the first deformable container 146 communicates with the first inlet 1400 and the first outlet 1402. In this embodiment, the first deformable container 146 may be fixed to the first base 140 and the carrier 144 by screws, so as to facilitate disassembly and assembly. One of the two first sealing members 150 is sandwiched in between the first base 140 and the first deformable container 146, and the other one of the two first sealing members 150 is sandwiched in between the carrier 144 and the first deformable container 146. The first sealing members 150 can prevent a fluid from leaking from the first deformable container 146 to the outside and prevent the outside gas from entering the first deformable container 146. The first sealing members 150 may be O-rings or the like according to practical applications.

The second base 152 has a second inlet 1520 and a second outlet 1522. The two second check valves 154a, 154b are disposed at the second inlet 1520 and the second outlet 1522. The second deformable container 156 is connected to the second base 152 and the carrier 144, and the second deformable container 156 communicates with the second inlet 1520 and the second outlet 1522. In this embodiment, the second deformable container 156 may be fixed to the second base 152 and the carrier 144 by screws, so as to facilitate disassembly and assembly. One of the two second sealing members 158 is sandwiched in between the second base 152 and the second deformable container 156, and the other one of the two second sealing members 158 is sandwiched in between the carrier 144 and the second deformable container 156. The second sealing members 158 can prevent a fluid from leaking from the second deformable container 156 to the outside and prevent the outside gas from entering the second deformable container 156. The second sealing members 158 may be O-rings or the like according to practical applications.

The driving mechanism 148 is connected to the carrier 144. The driving mechanism 148 is configured to drive the carrier 144 to reciprocate, such that the carrier 144 drives the first deformable container 146 and the second deformable container 156 to expand or contract, as shown in FIGS. 5 and 6. In this embodiment, the first deformable container 146 and the second deformable container 156 are located at opposite sides of the carrier 144. Thus, when the first deformable container 146 expands, the second deformable container 156 contracts; and when the first deformable container 146 contracts, the second deformable container 156 expands. In this embodiment, the first deformable container 146 and the second deformable container 156 may be, but are not limited to, bellows. In practical applications, the first deformable container 146 and the second deformable container 156 may be made of plastic or metal.

In this embodiment, the driving mechanism 148 may comprise a motor 1480, a crankshaft 1482 and a linkage member 1484. The crankshaft 1482 is connected to the motor 1480 and the linkage member 1484, and the linkage member 1484 is connected to the carrier 144. The motor 1480 is configured to drive the crankshaft 1482 to rotate. Furthermore, the support members 160 are connected to the first base 140 and the second base 152. The carrier 144 is movably sleeved on the support members 160. When the motor 1480 drives the crankshaft 1482 to rotate, the crankshaft 1482 drives the linkage member 1484 to move to drive the carrier 144 to reciprocate along the support members 160. Accordingly, the carrier 144 will drive the first deformable container 146 and the second deformable container 156 to expand or contract.

As shown in FIG. 3, the first check valve 142a may comprise a stop portion 1420, a restraining portion 1422, a plunger 1424 and an elastic member 1426. The plunger 1424 is movably disposed between the stop portion 1420 and the restraining portion 1422. A pillar 1428 of the plunger 1424 is disposed in a hole 1430 of the restraining portion 1422. The elastic member 1426 is sleeved on the pillar 1428 of the plunger 1424 and abuts against the restraining portion 1422. In this embodiment, the elastic member 1426 may be, but is not limited to, a spring. When the plunger 1424 moves toward the restraining portion 1422, the first check valve 142a is opened and the plunger 1424 compresses the elastic member 1426. When the elastic member 1426 forces the plunger 1424 to return toward the stop portion 1420, the stop portion 1420 stops the plunger 1424, such that the first check valve 142a is closed.

It should be noted that the structures and configurations of the first check valve 142b and the second check valves 154a, 154b are the same as those of the first check valve 142a, i.e. each of the first check valve 142b and the second check valves 154a, 154b comprises the stop portion 1420, the restraining portion 1422, the plunger 1424 and the elastic member 1426 shown in FIG. 3. The principles of the first check valve 142a, 142b and the second check valve 154a, 154b are the same, so the repeated explanation will not be depicted herein again.

As shown in FIG. 4, the immersion cooling system 1 comprises a cooling tank 10, a cooling device 12 and the aforesaid delivery device 14. In this embodiment, the cooling device 12 may comprise a fan, a condenser or other cooling components according to practical applications. The cooling device 12 may be connected to the cooling tank 10 by a pipeline 16. The first inlet 1400 of the first base 140 and the second inlet 1520 of the second base 152 may be connected to the cooling tank 10 by another pipeline 18. The first outlet 1402 of the first base 140 and the second outlet 1522 of the second base 152 may be connected to the cooling device 12 by another pipeline 20. The cooling tank 10 may store a cooling liquid (e.g. dielectric liquid) with a low boiling point. An electronic component (not shown) may be immersed in the cooling liquid of the cooling tank 10. The cooling liquid evaporates into gas after absorbing the heat generated by the electronic component. Then, the delivery device 14 draws the gas into the first deformable container 146 and the second deformable container 156 through the pipeline 18 and then delivers the gas to the cooling device 12 through the pipeline 20.

As shown in FIG. 5, when the driving mechanism 148 drives the carrier 144 to move upward, the carrier 144 drives the first deformable container 146 to expand. At this time, due to the variation of pressure in the first deformable container 146, the first check valve 142a is opened and the first check valve 142b is closed. Thus, the gas is able to enter and stored in the first deformable container 146 from the first check valve 142a and the first inlet 1400 of the first base 140. Furthermore, when the driving mechanism 148 drives the carrier 144 to move upward, the carrier 144 drives the second deformable container 156 to contract. At this time, due to the variation of pressure in the second deformable container 156, the second check valve 154a is closed and the second check valve 154b is opened. Thus, the gas in the second deformable container 156 is able to flow out from the second outlet 1522 of the second base 152 and the second check valve 154b.

As shown in FIG. 6, when the driving mechanism 148 drives the carrier 144 to move downward, the carrier 144 drives the first deformable container 146 to contract. At this time, due to the variation of pressure in the first deformable container 146, the first check valve 142a is closed and the first check valve 142b is opened. Thus, the gas in the first deformable container 146 is able to flow out from the first outlet 1402 of the first base 140 and the first check valve 142b. Furthermore, when the driving mechanism 148 drives the carrier 144 to move downward, the carrier 144 drives the second deformable container 156 to expand. At this time, due to the variation of pressure in the second deformable container 156, the second check valve 154a is opened and the second check valve 154b is closed. Thus, the gas is able to enter and stored in the second deformable container 156 from the second check valve 154a and the second inlet 1520 of the second base 152.

When the gas is delivered to the cooling device 12 through the pipeline 20, the cooling device 12 cools the gas into the cooling liquid. The cooling liquid is recycled to the cooling tank through the pipeline 16. Accordingly, the cooling liquid can be continuously recycled and reused.

It should be noted that the delivery device 14 of the invention may also omit the second deformable container 156 and the related components. When the delivery device 14 is equipped with the first deformable container 146 and the second deformable container 156 at the same time, the efficiency of recycling the cooling liquid can be increased.

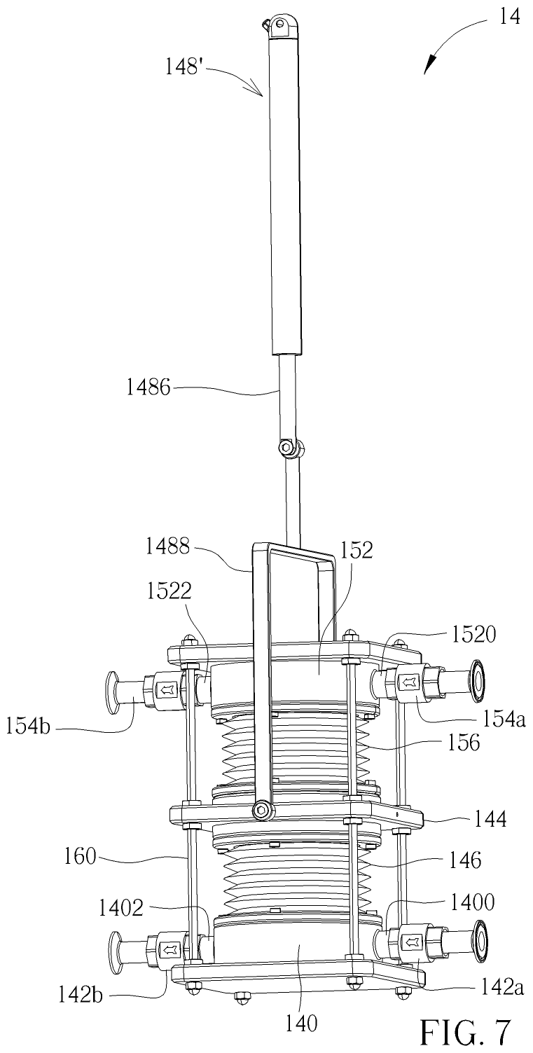

Referring to FIG. 7, FIG. 7 is a perspective view illustrating the delivery device 14 according to another embodiment of the invention.

In another embodiment, the aforesaid driving mechanism 148 may be replaced by a driving mechanism 148′ shown in FIG. 7. As shown in FIG. 7, the driving mechanism 148′ may comprise an actuating member 1486 and a linkage member 1488. The actuating member 1486 is connected to the linkage member 1488 and the linkage member 1488 is connected to the carrier 144. The actuating member 1486 is configured to drive the linkage member 1488 to move upward and downward to drive the carrier 144 to reciprocate. Accordingly, the carrier 144 will drive the first deformable container 146 and the second deformable container 156 to expand or contract. In this embodiment, the actuating member 1486 may be, but is not limited to, a linear actuator. It should be noted that the same elements in FIG. 7 and FIGS. 1-6 are represented by the same numerals, so the repeated explanation will not be depicted herein again.

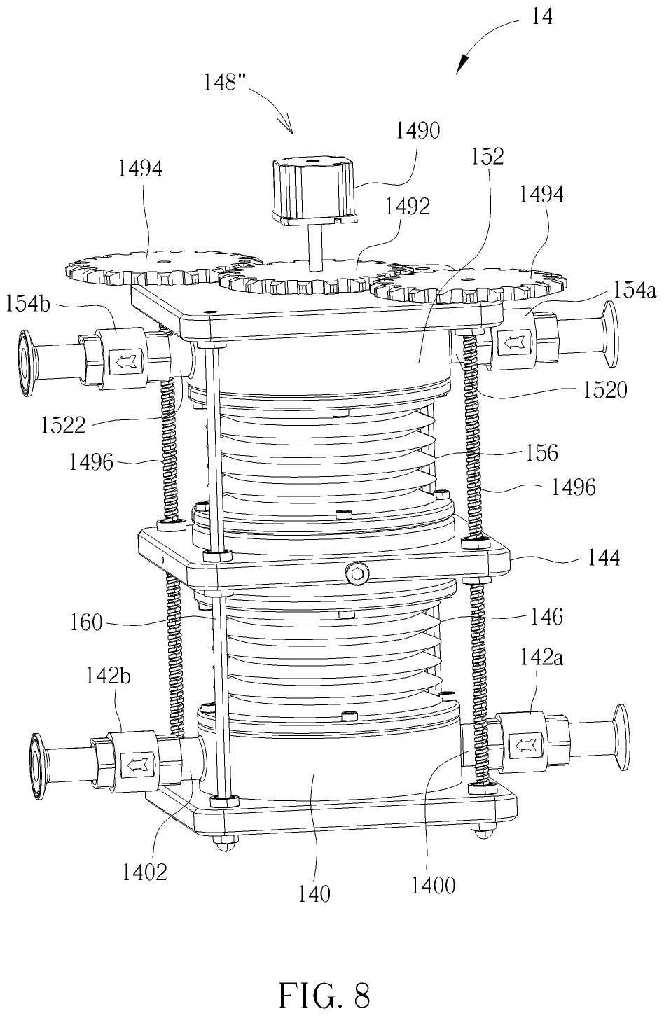

Referring to FIG. 8, FIG. 8 is a perspective view illustrating the delivery device 14 according to another embodiment of the invention.

In another embodiment, the aforesaid driving mechanism 148 may be replaced by a driving mechanism 148″ shown in FIG. 8. As shown in FIG. 8, the driving mechanism 148″ may comprise a motor 1490, a driving gear 1492, two driven gears 1494 and two screw rods 1496. The driving gear 1492 is connected to the motor 1490 and meshes with the two driven gears 1494. The two screw rods 1496 are connected to the first base 140, the carrier 144 and the two driven gears 1494. In this embodiment, two support members 160 mentioned in the above may be replaced by the two screw rods 1496. Furthermore, the carrier 144 has two screw holes meshing with the two screw rods 1496. The motor 1490 is configured to drive the driving gear 1492 to rotate. When the motor 1490 drives the driving gear 1492 to rotate, the driving gear 1492 drives the two driven gears 1494 to rotate and the two driven gears 1494 drives the two screw rods 1496 to rotate to drive the carrier 144 to reciprocate. Accordingly, the carrier 144 will drive the first deformable container 146 and the second deformable container 156 to expand or contract. It should be noted that the same elements in FIG. 8 and FIGS. 1-6 are represented by the same numerals, so the repeated explanation will not be depicted herein again.

It should be noted that in addition to using the delivery device 14 to deliver gas for the immersion cooling system 1, the delivery device 14 may also be used to deliver single phase liquid or other chemical substances according to practical applications.

As mentioned in the above, the invention connects the deformable container and the driving mechanism to the carrier. When the driving mechanism drives the carrier to reciprocate, the carrier drives the deformable container to expand or contract, so as to deliver a fluid through the inlet and the outlet of the base. Since the driving mechanism is connected to the carrier, the driving mechanism is not in contact with the fluid in the deformable container. Accordingly, the delivery device of the invention can prevent the delivered fluid from being contaminated by the driving mechanism. Furthermore, the driving mechanism and the deformable container do not need mechanical seal and the invention may dispose the sealing members between the base, the deformable container and the carrier to prevent the fluid from leaking from the deformable container to the outside. Moreover, the deformable container and the driving mechanism can be disassembled and assembled separately, such that the maintenance is simple.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A delivery device comprising:
a first base having a first inlet and a first outlet;
two first check valves disposed at the first inlet and the first outlet;
a carrier;
a first deformable container connected to the first base and the carrier, the first deformable container communicating with the first inlet and the first outlet; and
a driving mechanism connected to the carrier;
wherein the driving mechanism drives the carrier to reciprocate, such that the carrier drives the first deformable container to expand or contract.

2. The delivery device of claim 1, further comprising two first sealing members, one of the two first sealing members being sandwiched in between the first base and the first deformable container, and the other one of the two first sealing members being sandwiched in between the carrier and the first deformable container.

3. The delivery device of claim 1, wherein the driving mechanism comprises a motor, a crankshaft and a linkage member, the crankshaft is connected to the motor and the linkage member, and the linkage member is connected to the carrier; wherein the motor drives the crankshaft to rotate and the crankshaft drives the linkage member to move to drive the carrier to reciprocate.

4. The delivery device of claim 1, wherein the driving mechanism comprises an actuating member and a linkage member, the actuating member is connected to the linkage member, and the linkage member is connected to the carrier; wherein the actuating member drives the linkage member to move to drive the carrier to reciprocate.

5. The delivery device of claim 1, wherein the driving mechanism comprises a motor, a driving gear, two driven gears and two screw rods, the driving gear is connected to the motor and meshes with the two driven gears, and the two screw rods are connected to the first base, the carrier and the two driven gears; wherein the motor drives the driving gear to rotate, the driving gear drives the two driven gears to rotate, and the two driven gears drives the two screw rods to rotate to drive the carrier to reciprocate.

6. The delivery device of claim 1, further comprising:
a second base having a second inlet and a second outlet;
two second check valves disposed at the second inlet and the second outlet; and
a second deformable container connected to the second base and the carrier, deformable container communicating with the second inlet and the second outlet, the first deformable container and the second deformable container being located at opposite sides of the carrier;
wherein the driving mechanism drives the carrier to reciprocate, such that the carrier drives the second deformable container to expand or contract; when the first deformable container expands, the second deformable container contracts; and when the first deformable container contracts, the second deformable container expands.

7. The delivery device of claim 6, further comprising two second sealing members, one of the two second sealing members being sandwiched in between the second base and the second deformable container, and the other one of the two second sealing members being sandwiched in between the carrier and the second deformable container.

8. The delivery device of claim 6, wherein each of the two first check valves and the two second check valves comprises a stop portion, a restraining portion, a plunger and an elastic member, the plunger is movably disposed between the stop portion and the restraining portion, a pillar of the plunger is disposed in a hole of the restraining portion, and the elastic member is sleeved on the pillar and abuts against the restraining portion.

9. The delivery device of claim 6, wherein the first deformable container and the second deformable container are bellows.

10. The delivery device of claim 6, further comprising a plurality of support members connected to the first base and the second base, and the carrier being movably sleeved on the support members.

11. An immersion cooling system with a delivery device comprising:
a cooling tank;
a cooling device connected to the cooling tank; and
the delivery device comprising:
a first base having a first inlet and a first outlet, the first inlet being connected to the cooling tank, the first outlet being connected to the cooling device;
two first check valves disposed at the first inlet and the first outlet;
a carrier;
a first deformable container connected to the first base and the carrier, the first deformable container communicating with the first inlet and the first outlet; and
a driving mechanism connected to the carrier;
wherein the driving mechanism drives the carrier to reciprocate, such that the carrier drives the first deformable container to expand or contract.

12. The immersion cooling system of claim 11, wherein the delivery device further comprises two first sealing members, one of the two first sealing members is sandwiched in between the first base and the first deformable container, and the other one of the two first sealing members is sandwiched in between the carrier and the first deformable container.

13. The immersion cooling system of claim 11, wherein the driving mechanism comprises a motor, a crankshaft and a linkage member, the crankshaft is connected to the motor and the linkage member, and the linkage member is connected to the carrier; wherein the motor drives the crankshaft to rotate and the crankshaft drives the linkage member to move to drive the carrier to reciprocate.

14. The immersion cooling system of claim 11, wherein the driving mechanism comprises an actuating member and a linkage member, the actuating member is connected to the linkage member, and the linkage member is connected to the carrier; wherein the actuating member drives the linkage member to move to drive the carrier to reciprocate.

15. The immersion cooling system of claim 11, wherein the driving mechanism comprises a motor, a driving gear, two driven gears and two screw rods, the driving gear is connected to the motor and meshes with the two driven gears, and the two screw rods are connected to the first base, the carrier and the two driven gears; wherein the motor drives the driving gear to rotate, the driving gear drives the two driven gears to rotate, and the two driven gears drives the two screw rods to rotate to drive the carrier to reciprocate.

16. The immersion cooling system of claim 11, wherein the delivery device further comprises:
a second base having a second inlet and a second outlet, the second inlet being connected to the cooling tank, the second outlet being connected to the cooling device;
two second check valves disposed at the second inlet and the second outlet; and
a second deformable container connected to the second base and the carrier, the second deformable container communicating with the second inlet and the second outlet, the first deformable container and the second deformable container being located at opposite sides of the carrier;
wherein the driving mechanism drives the carrier to reciprocate, such that the carrier drives the second deformable container to expand or contract; when the first deformable container expands, the second deformable container contracts; and when the first deformable container contracts, the second deformable container expands.

17. The immersion cooling system of claim 16, wherein the delivery device further comprises two second sealing members, one of the two second sealing members is sandwiched in between the second base and the second deformable container, and the other one of the two second sealing members is sandwiched in between the carrier and the second deformable container.

18. The immersion cooling system of claim 16, wherein each of the two first check valves and the two second check valves comprises a stop portion, a restraining portion, a plunger and an elastic member, the plunger is movably disposed between the stop portion and the restraining portion, a pillar of the plunger is disposed in a hole of the restraining portion, and the elastic member is sleeved on the pillar and abuts against the restraining portion.

19. The immersion cooling system of claim 16, wherein the first deformable container and the second deformable container are bellows.

20. The immersion cooling system of claim 16, wherein the delivery device further comprises a plurality of support members connected to the first base and the second base, and the carrier is movably sleeved on the support members.
